(19) United States
(12) Patent Application Publication
(10) Pub. No.: US 2003/0073289 A1
(43) Pub. Date: Apr. 17, 2003

(54) Trench-gate semiconductor devices and their manufacture

(75) Inventors: Steven J. Curry, Stockport (GB); Steven T. Peake, Warrington (GB)

Correspondence Address: Corporate Patent Counsel, U.S. Philips Corporation, 580 White Plains Road, Tarrytown, NY, 10591, US

(73) Assignee: Koninklijke Philips Electronics N.V.

(21) Appl. No.: 10/246,171

(22) Filed: Sep. 18, 2002

(30) Foreign Application Priority Data
Oct. 11, 2001 (GB) 0124371.6
Jun. 26, 2002 (GB) 0214730.4

(51) Int. Cl. H01L 21/336; H01L 21/3205; H01L 21/4763

(52) U.S. Cl. 438/270; 438/589

(57) ABSTRACT

Trench-gate field-effect semiconductor devices, for example cellular power MOSFETs with compact geometries, comprise a semiconductor body (10) into which the trench-gate (11) extends from a surface-adjacent source region (13) through a channel-accommodating region (15) of opposite conductivity type (p) and into an underlying drain drift region (14). This invention provides the gate trench (20) with a width (w) that is smaller than its depth (d) and that tapers increasingly towards the bottom of the gate trench (20) to reduce the width (w) of the trench-gate (11) at a greater rate in the drain drift region (14) than in the channel-accommodating region (15).

This invention relates to trench-gate field-effect semiconductor devices, for example cellular power MOSFETs (insulated-gate field-effect transistors), and to their manufacture with compact geometries.

Trench-gate field-effect semiconductor devices are known, having a trench-gate that extends from a source region of a first conductivity type (e.g. n-type) through a channel-accommodating region of a second conductivity type (e.g. p-type) and into a drain drift region of the first conductivity type.

United States patent specification U.S. Pat. No. 6,087,224 (our reference PHB34245) discloses an advantageous method for manufacturing such trench-gate semiconductor devices with a densely-packed layout, wherein:

(a) a narrow window is defined by providing sidewall extensions (commonly termed “spacers”) at the sidewalls of a wider window in a first mask at a surface of a semiconductor body,

(b) a trench is etched into the body at the narrow window, and the gate is provided in the trench, and

(c) the source region is provided so as to be self-aligned with the trench-gate by means of the spacers.

This method permits the use of self-aligned masking techniques in a flexible device process with good reproducibility. In particular, by using the spacers in different stages, narrow trench-gates can be formed and the source region and a contact window for a source electrode can be determined in a self-aligned manner with respect to this narrow trench. The whole contents of U.S. Pat. No. 6,087,224 are hereby incorporated herein as reference material.

U.S. Pat. No. 6,087,224 discloses various forms of the method. Thus, for example, the source region and/or channel-accommodating region may be provided either before or after forming the trench-gate, either a deep or shallow more highly-doped region may be provided (also in a self-aligned manner) in the channel-accommodating region, either a doped-semiconductor or a metal or silicide material may be used for the gate, and either an oxidised or deposited insulating overlayer may be provided (also in a self-aligned manner) over the trench-gate.

It is an aim of the present invention to improve the characteristics of such trench-gate field-effect devices, particularly but not exclusively for so-called VRM (voltage regulator module) applications, and to provide methods of manufacturing such devices.

According to a first aspect of the invention there is provided a trench-gate field-effect semiconductor device, wherein the gate trench has a width that is smaller than its depth in the semiconductor body and that tapers increasingly towards the bottom of the gate trench to reduce the width of the trench-gate at a greater rate in the drain drift region than in the channel-accommodating region.

For VRM applications in the PC motherboard market, the demands are increasing for trench-gate MOSFETs with low on-state resistance and fast low switching loss. The requirements of this computer market are such that the trench technology being developed must meet targets set by a market where new processor generations are operating at increased frequencies (>1 MHz) and at high load currents.

For a typical VRM application, two trench-gate MOSFETs are required, each MOSFET requiring a different optimization. The first MOSFET is required to offer a very low on-state resistance and is typically labelled a synch-FET. To achieve a very low on-state resistance, the channel area per-unit area of silicon must be as high as can be possibly achieved. By reducing the cell pitch the channel area per unit area of silicon can be significantly increased. The second type of MOSFET is required to offer very low switching losses at very high frequencies and is typically labelled a control-FET. To achieve this requirement, a trade off between on-state resistance and Miller capacitance is needed. The trade off can be optimised by reducing the so-called “Figure of Merit” (Rdson*Qgd) as much as possible. This trade off typically requires the cell pitch to be increased to lower the Miller capacitance to such a value that the Figure of Merit of the MOSFET is minimised. However, an increase in pitch increases the on-state resistance. Another method of reducing the Miller capacitance is to reduce the trench width, thereby reducing the peripheral area of the gate-drain capacitor at the bottom of each gate trench. However, a reduction in trench width increases the gate resistance.

In specific examples of MOSFET embodiments in U.S. Pat. No. 6,087,224, the cell pitch was 5 μm (micrometres; microns) or less, and the width of the gate trench was about 1 μm. The width of this gate trench was the same throughout the depth of the trench, i.e. a rectangular trench shape.

The present invention enables the provision of a densely packed trench technology with a much narrower sub-micron gate trench width, that is much smaller than its depth and that reduces in size (with increasing taper) towards the bottom of the trench. Various advantageous device features resulting there-from are set out in claims 1 to 7.

Thus, trench-gate semiconductor devices with such tapered gate trenches provide a first aspect of the present invention. The depth of the gate trench can be more than 4 times (for example, 6 or more times) larger than its width in the channel-accommodating region, and the width may taper over the bottom half of the trench to less than 0.7 (or even 0.5) of its initial value. In particular examples, the trench width may taper from, for example, about 0.2 μm or less in the channel-accommodating region to, for example, less than 0.15 μm (even about 0.12 μm and/or 0.1 μm) in the drain drift region.

According to a second aspect of the invention there is provided a method of manufacturing such a device. Various advantageous method features are set out in claims 8 to 12. Such features are consistent with the use of self-aligned technologies. Thus, a suitably narrow and deep tapered trench can be formed with an adaptation of the fully self-aligned process of U.S. Pat. No. 6,087,224.

The effect of the taper is such as to reduce significantly the Miller capacitance, as compared with a rectangular trench shape. This reduction in Miller capacitance is due to the decreased gate to drain periphery in the lower half of the trench and/or the optional combination of a thick insulator material with the narrower bottom portion of the tapered trench. Hence, Qgd (and therefore the Figure of Merit) is lower with the tapered trench, as compared with a rectangular trench shape. Some reduction in on-state drain resistance may also be achieved due to better current spreading from the conduction channel to below the narrowed trench bottom. Due to the greater width in the upper part of the tapered trench, there is less increase in gate resistance, as compared with a rectangular trench shape of the same narrowed width as the bottom of the tapered trench.

The effect of a taper of the trench in the channel-accommodating region is to increase the length of the channel, and this may increase undesirably the specific on-state resistance Rdson between source and drain. Therefore, preferably there is only a little (or even no) taper of the trench in the channel-accommodating region. In any case, the present invention provides the advantage that the rate of width-reduction (taper) of the trench is greater in the drain drift region than in the channel-accommodating region.

The increased taper of the trench in the drain drift region is also beneficial when the channel-accommodating region is provided in the semiconductor body after the trench-gate. The diffusion rate of dopant in the semiconductor body portion adjacent to the trench side-walls decreases (i.e. slows) as the taper increases. Thus, the increasingly tapered lower portion of the trench assists in controlling the depth of the subsequently-provided channel-accommodating region adjacent to the trench. This depth control is important in controlling channel length and in ensuring that the dopant does not diffuse under the trench bottom where it may prevent channel connection to the drain drift region.

The development of this novel trench-gate technology in accordance with the invention permits both the synch-FET and the Control-FET of a VRM, with their different optimisation criteria, to be fabricated using the same fully self-aligned process. By so increasing the cell density, for a fixed active area, the amount of channel is increased significantly. The cell pitch for the synch-FET may be about 1 μm (micrometres) or less. Simulations have shown that for a 1 μm cell pitch, by increasing the channel density a specific on-state drain resistance (including spreading resistance) of less than 15 mΩ.mm² at 10V can be achieved for a device with a 30V n-epitaxial silicon specification. The versatility of the fully self-aligned process permits the cell pitch to be increased for the control-FET, whilst retaining the 0.2 μm tapered trench width. By increasing the pitch but keeping the 0.2 μm tapered trench width, switching losses (which are a function of Miller capacitance) can be minimised. Simulations have shown that for a 3 μm cell pitch (with a 0.2 μm trench width) a Figure of Merit (Rdson*Qgd) of less than 20 is possible.

A further possible benefit of adopting a tapered shape for the gate trench is that it can facilitate the provision of a thick insulator at the bottom of the trench, where it may be retained to further reduce Qgd. A thick oxide may be deposited in the trench bottom. Alternatively, the trench may be lined with a silicon nitride layer which is then etched away from the bottom of the trench but retained at the side-walls of the trench. Thereafter, thick oxide may be grown at the bottom of the trench and part-way up the tapered side-walls of the trench in the drain drift region, while using the retained silicon nitride layer to mask the side-walls of the trench adjacent to the upper first portion.

These and other features in accordance with the present invention are illustrated in embodiments of the invention that are now described, by way of example, with reference to the accompanying drawings, in which:

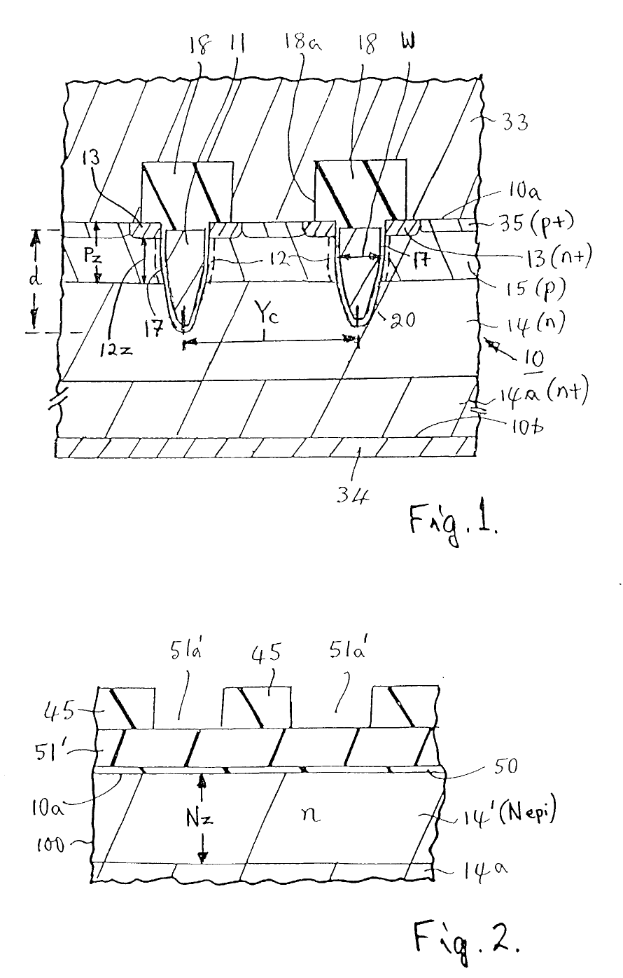

FIG. 1 is a cross-sectional view of an active central part of one example of a trench-gate semiconductor device in accordance with the invention;

FIGS. 2 to 5 are cross-sectional views of the part of FIG. 1 at successive stages in its manufacture by one example of a method in accordance with the invention;

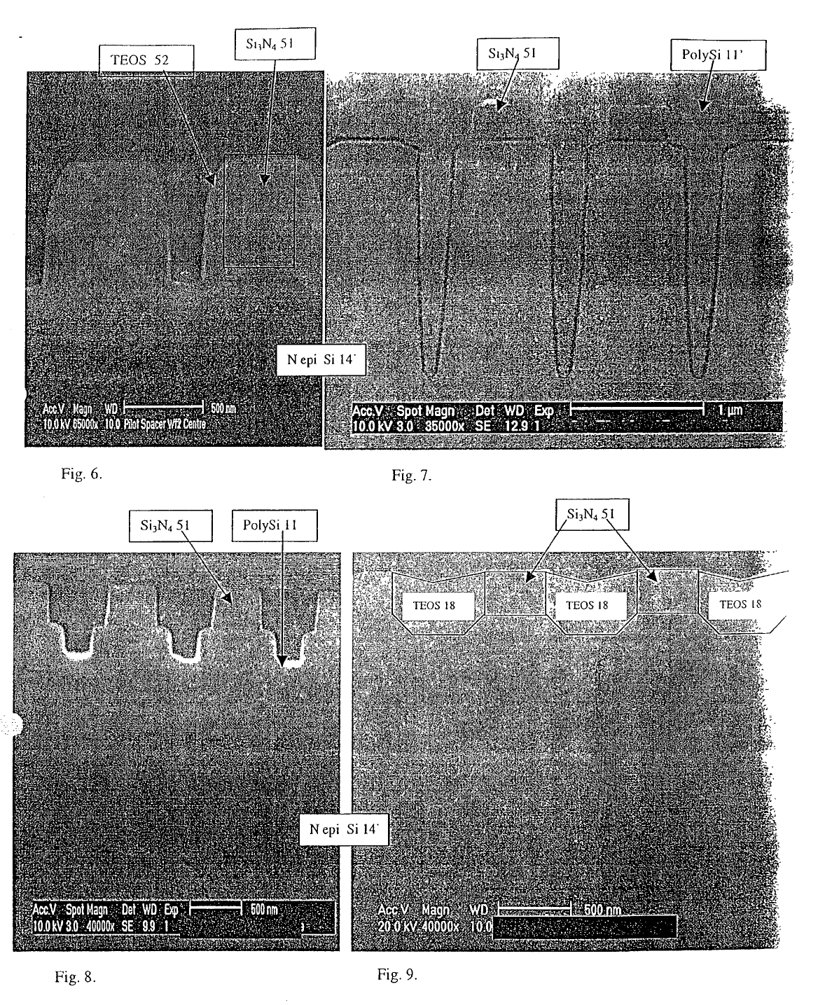

FIGS. 6 to 9 are SEM photographs of such a part when fabricated, showing actual cross-sections of the tapered gate trench and its etch mask;

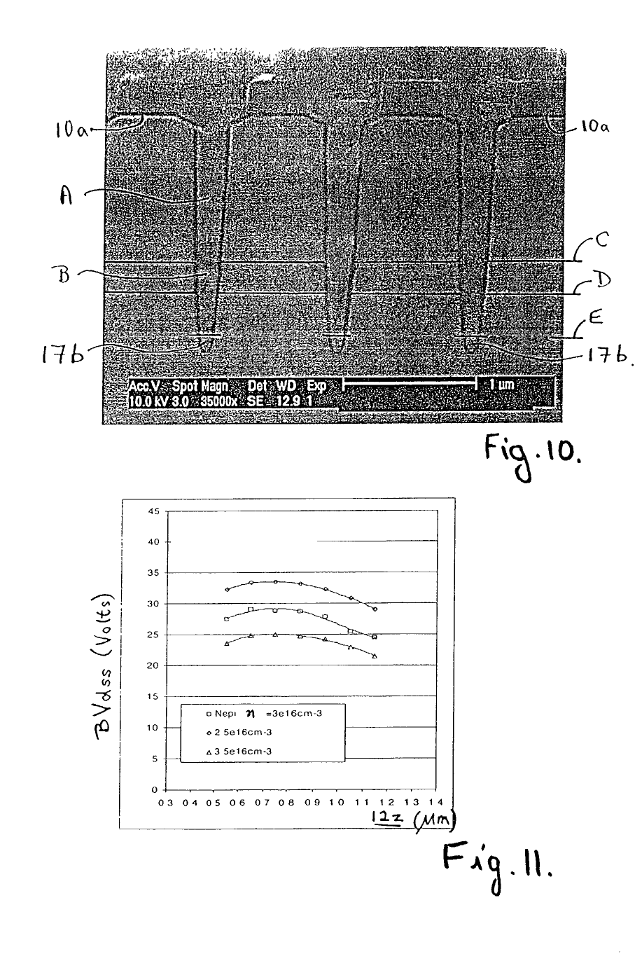

FIG. 10 is a copy of FIG. 7 that is annotated to examine the different widths of the tapered trench at different depths at which various device features may be provided;

FIGS. 11 to 15 are simulation results of the variation of device characteristics with different device parameters, and including also some measured values, wherein:

FIG. 11 is a plot of breakdown voltage BVdss in Volts against channel length 12z in μm, for different Nepi doping concentrations n in cm⁻³;

FIG. 12 is a plot of specific on-state resistance spRdson in mOhms.mm² against Nepi doping concentration n in 10¹⁶ donor atoms cm⁻³, for different Nepi thicknesses Nz;

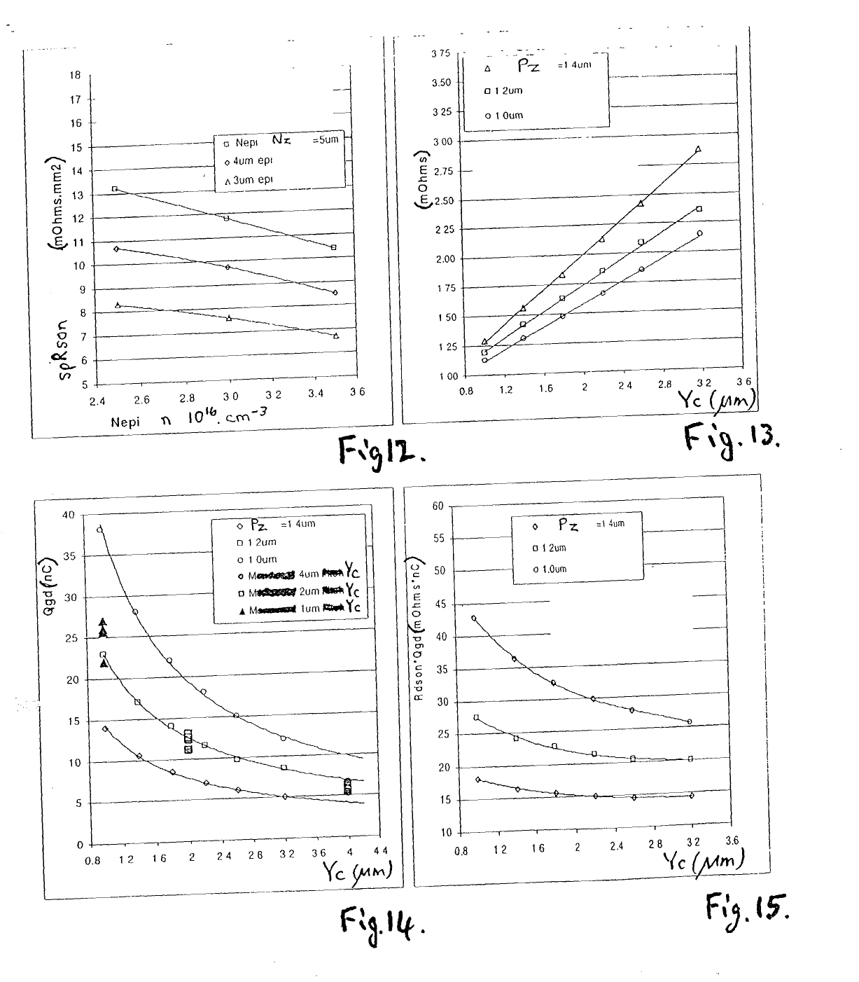

FIG. 13 is a plot of on-state drain resistance Rdson in mOhms (for a 7.32 mm² active area) against cell pitch Yc in μm, for different depths Pz of the p-type region 15;

FIG. 14 is a plot of gate-drain charge Qgd in nC at Vds=12V against cell pitch Yc in μm, for different depths Pz of the p-type region 15; and

FIG. 15 is a plot of the Figure of Merit Rdson*Qgd in mOhm s*nC against cell pitch Yc in μm, for different depths Pz of the p-type region 15

It should be noted that FIGS. 1 to 5 are diagrammatic, with the relative dimensions and proportions of various parts of these drawings being shown exaggerated or reduced in size, for the sake of clarity and convenience in the drawings. The same reference signs are generally used to refer to corresponding or similar features in modified and different embodiments.

FIG. 1 illustrates an exemplary embodiment of a cellular power MOSFET device having an insulated trench-gate 11. In the transistor cell areas of this device, a channel-accommodating region 15 of a second conductivity type (i.e. p-type in this example) separates source and drain regions 13 and 14, respectively, of a first conductivity type (n-type in this example). The drain region 14 is common to all the cells. The gate 11 is present in a trench 20 that extends through the regions 13 and 15 into an underlying portion of the drain region 14. The gate 11 is capacitively coupled to the channel-accommodating region 15 by an intermediate dielectric layer 17 at the walls of the trench 20. This dielectric layer 17 is of substantially uniform thickness, at least along the side-walls of the trench 20. The application of a voltage signal to the gate 11 in the on-state of the device serves in known manner for inducing a conduction channel 12 in the region 15 and for controlling current flow in this conduction channel 12 between the source and drain regions 13 and 14.

The source region 13 is located adjacent to the top major surface 10a of the device body 10, where regions 13 and 15 are contacted by a source electrode 33. The electrode 33 contacts a more highly doped portion 35 of the channel-accommodating region 15. The trench-gate 11 is insulated from the overlying electrode 33 by an intermediate insulating overlayer 18 (also termed capping layer). FIG. 1 shows a vertical power device structure. The region 14 is a drain-drift region, which is typically formed by an epitaxial layer of high resistivity on a more highly-doped substrate region 14a of the same conductivity type. In the vertical device configuration of FIG. 1, this substrate region 14a is contacted at the bottom major surface 10b of the device body 10 by a drain electrode 34.

Typically the device body 10 is of monocrystalline silicon, and the gate 11 may typically be of conductively-doped polycrystalline silicon. Typically, the intermediate gate dielectric layer 17 is of thermally grown silicon dioxide or deposited silicon dioxide.

The device of FIG. 1 has a deep but narrow (sub-micron) tapered gate trench 20 in accordance with the present invention. The gate trench width w is much smaller than its depth d and reduces in size (i.e. tapers) increasingly towards the bottom of the trench. A particular example is described hereinafter with reference to the SEM photograph of FIG. 10. The rate of width-reduction (taper) of the trench 20 is greater in the drain drift region 14 than in the channel-accommodating region 15. The relative depths of the trench 20 and channel-accommodating region 15 can be chosen such that there is very little (in fact, hardly any) taper of the trench 20 in the region 15.

The taper serves to reduce significantly the Miller capacitance, due to a decrease in gate-to-drain periphery in the lower part of the trench 20 as compared with a rectangular trench shape. Some reduction in on-state drain resistance is also achieved due to better current spreading from the conduction channel 12 to below the gate trench 20 in the drain drift region 14.

Such a trench-gate semiconductor device with tapered gate trench in accordance with the first aspect of the present invention can be manufactured by a method in accordance with the second aspect of the invention. Such a method may be an adaptation of the fully self-aligned process of U.S. Pat. No. 6,087,224.

Thus, the manufacture of the device of FIG. 1 may include the following sequence of stages:

(a) providing a semiconductor wafer body 100 (for forming the device body 10) having an upper first portion where the channel-accommodating region 15 is present or is to be provided and having a lower second portion that is to form the drain drift region 14,

(b) defining a narrow trench-etch window 52a (FIGS. 4 and 6), by providing sidewall extensions 52 (commonly termed “spacers” 52) at the sidewalls of a wider window 51a in a first mask 51 (FIG. 3) at the top surface 10a of the semiconductor wafer body 100,

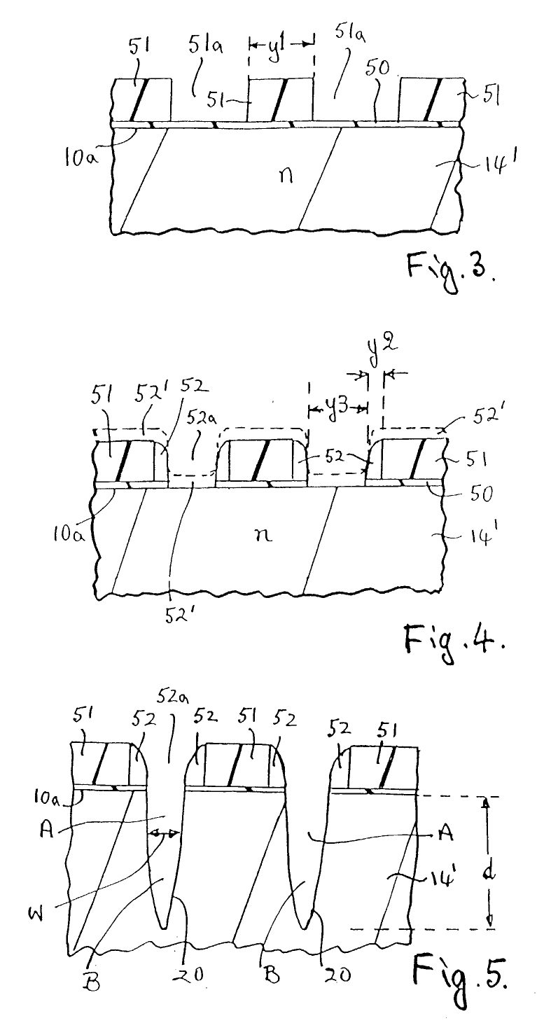

(c) etching the tapered trench 20 deeply into the body 100 at the narrow window 52a (FIG. 5), and

(d) providing the insulated gate structure 11, 17 in the tapered trench 20 (FIGS. 1 and 7).

Preferably, these stages (b) to (d) are carried out before providing the source region 13, the channel-accommodating region 15, and its more highly-doped contact portion 35 (FIG. 1), for example by respective dopant ion implantations. The source region 13 may be self-aligned with the trench-gate 11 by means of the spacers 52, for example as described in U.S. Pat. No. 6,087,224.

The single masking pattern 45, 51 (which is photo-lithographically defined in FIG. 2) is used for determining, in a self-aligned manner, all subsequent windows (for etching, gate-planarisation, doping, contacting, etc.) in the cell areas shown in FIGS. 1 to 10. This self-alignment simplifies the manufacture and permits a reproducible close spacing of the transistor cells, for example, with a cell pitch Yc of about 1 micrometre or less for a synch-FET. A wider cell pitch Yc can be used for a control-FET.

The cell pitch and the layout geometry of the device is determined by the photolithographic and etching stage illustrated in FIGS. 2 and 3. No plan view of the cellular layout geometry is shown in the drawings, because the method of FIGS. 1 to 10 may be used for quite different, known cell geometries. Thus, for example the cells may have a square geometry or a close-packed hexagonal geometry, or they may have an elongate stripe geometry. In each case, the tapered trench 20 (with its gate 11) extends around the boundary of each cell.

The attached Figures show only a few cells, but typically the device comprises many thousands of these parallel cells between the electrodes 33 and 34. The active cellular area of the device may be bounded around the periphery of the device body 10 by various known peripheral termination schemes (also not shown). Such schemes normally include the formation of a thick field-oxide layer in the peripheral device area at the body surface 10a, before the transistor cell fabrication steps. Furthermore, various known circuits (such as gate-control circuits) may be integrated with the device in an area of the body 10, between the active cellular area and the peripheral termination scheme. Typically their circuit elements may be fabricated with their own layout in this circuit area using some of the same masking and doping steps as are used for the transistor cells.

FIG. 2 illustrates the silicon body part of FIG. 1 at an early stage in the device manufacture when it comprises epitaxial layer 14′ (N epi of thickness Nz and doping n) on the more highly doped (n+) substrate 14a. In the specific example now described, a thick silicon nitride layer 51′ is deposited on a thin silicon dioxide layer 50 on the silicon body surface 10a. Typically the oxide layer 50 may be 30 nm to 50 nm thick. In a particular device embodiment, by way of a specific example, the nitride layer 51′ may be in the range of 0.4 μm to 0.51 μm thick, and window 51a may be about 0.51 μm wide.

The window 51a is defined using known photolithographic techniques. A photoresist mask 45 with a corresponding window 51a′ is provided on the nitride layer 51′ as illustrated in FIG. 2. This serves as an etchant mask for etching the window 51a into the layer 51′ to form the mask 51 illustrated in FIG. 3. This mask 51 and its associated windows (51a of FIG. 3 and narrowed window 52a of FIG. 4) have a layout geometry that defines the layout of the device cells and their pitch Yc.

Thus, the windows 51a & 52a define the gate boundary of the cells which is, for example, an hexagonal network in the case of a close-packaged hexagonal cellular geometry. In whatever layout geometry is chosen, the width y1 of the mask 51 between neighbouring windows 51a is chosen appropriately for the desired cell width and the area of contact window 18a for electrode 33.

A TEOS oxide layer 52′ is now contour deposited, on the top and sidewalls of the nitride mask 51 and at the bottom of the window 51a. This oxide layer 52′ is then etched back in known manner, using a directional etch, to remove it from the top of the nitride mask 51 and from the bottom of the window 51a, while leaving the spacers 52 at the sidewalls. The etch-back also removes the exposed thin oxide layer 50 from the window 52a. Typically, the contour-deposited oxide layer 52′ may be about 0.2 μm, so that the remaining width y2 of spacers 52 is in the range of 0.1 μm to 0.2 μm. FIG. 4 shows the resulting structure, with the narrower window 52a of width y3 as defined by the spacers 52 of width y2. An example of an actual structure at this stage is shown in the SEM photograph of FIG. 6, with a window width y3 of just less than 0.2 μm.

The deep and narrow, tapered trench 20 is now etched into the body 100 at the window 52a. Plasma etching is most conveniently used. As shown in FIGS. 2 to 5, the silicon body portion 14′ (into which the trench 20 is etched) preferably contains only a doping profile for the drain region 14, i.e. the dopant concentrations for regions 13 and 15 are not yet provided. This provides better control of the etching of trench 20, i.e. its etched shape is not affected by the dopant concentrations for regions 13 and 15. This doping profile n is that of the drain drift region. Thus, the body portion 14′ may be an area of an epitaxial layer that has a substantially homogeneous doping concentration n from the surface 10a to the substrate region 14a. In specific embodiments (see FIGS. 11 to 15, for example) the concentration n may be, for example, in the range of about 2×10¹⁶ to 3.5×10¹⁶ phosphorus or arsenic atoms cm⁻³. In another embodiment, the doping concentration n of this body portion 14′ may increase with depth from about 1×10¹⁶ to about 10¹⁷ adjacent to the substrate region 14a.

In the specific embodiment illustrated in FIGS. 7 and 10, the depth d to which the trench 20 is etched is about 8 times the width y3 of the narrowed window 52a. Thus, in this particular example, the trench 20 is etched to a depth d of just over 1.5 μm. FIG. 5 is a schematic representation of the trench etching. There is very little tapering of the trench over an etch depth of up to almost 4 times its initial width w. This is depicted by upper zone A of the trench 20 in FIG. 5. However, as this narrow trench 20 is etched deeper, the reactants in the plasma become increasingly depleted, so that the etching becomes less efficient. As a result, there occurs a reduction in the volume (and hence trench width) of silicon material that is etched away, so giving rise to an increasing taper. This effect is illustrated by lower zone B of the trench 20 in FIG. 5. It exploits the well-known phenomenon of a so-called “loading effect”, in which the etch rate is dependent on the amount of etchable surface exposed to the etchant. Another known effect, namely etch-product deposition, may also be used to restrict plasma flow in the trench. The parameters controlling such deposition at the upper sidewalls of an etched trench are discussed in, for example, United States patent specifications U.S. Pat. No. 6,284,666 and U.S. Pat. No. 4,784,720 and the references cited therein, the whole contents of which are hereby incorporated herein as reference material.

FIG. 7 is the clearest SEM photograph of the etched cross-section of trench 20, and so this photograph is repeated in FIG. 10 with added lines C, D, & E at different depths from the surface 10a. It should be noted that FIG. 7 represents a later stage of manufacture, after the oxide spacers 52 have been etched away, and after the trench 20 is lined with the gate dielectric 17 and filled with the polysilicon gate material 11. Thus, FIG. 7 shows some etching away of the surface 10a where the spacers 52 where present.

As can be seen from FIGS. 7 and 10, the trench width w adjacent to the surface 10a is about 0.24 μm, with only a very small taper to depth C of 1 μm from the surface 10a. The trench width w is about 0.18 μm at this depth C. The trench width has narrowed to about 0.15 μm at depth D of 1.2 μm, and continues to narrow to about 0.1 μm at depth E of 1.5 μm. Thus, the rate of width-reduction (taper) over the 0.5 μm from depth C to depth E is almost three times that over the first 1 μm from surface 10a to depth C. These different tapers can be exploited to advantage in relation to the depth to be chosen for the channel-accommodating region 15, as described below.

After etching the trench 20, the oxide spacers 52 may now be etched away to re-open the nitride window 51a. This etch also removes the thin oxide 50 under the oxide spacers 52. The gate dielectric layer 17 of substantially uniform thickness is then formed, for example by thermal oxidation of the silicon body portion 14′ at the walls of the trench 40. In the embodiment of FIGS. 1 to 9, this dielectric layer 17 lines the bottom as well as the sidewalls of the trench 20.

Thereafter, the gate 11 is provided in known manner, by depositing gate material 11′ to a thickness that is sufficient to fill the trench 20 and to extend above the window 51a and over the nitride mask 51, as illustrated in FIG. 7. Thereafter, the gate material 11′ is etched back to leave it forming the gate 11 in the trench 20. Typically, the gate 11 comprises doped polycrystalline silicon or other semiconductor material. Its doping concentration may be provided while the material 11′ is being deposited or after deposition, for example after etch-back.

Thus, in this self-aligned process, the trench etch area is defined by patterning nitride 51, depositing a contour oxide 52′, and etching this contour oxide to form spacers 52. The tapered trench 20 is then etched, the spacers 52 are removed, a gate oxide is provided, and the gate 11 is then provided in the trench 20. Thereafter, the n+ source region 13 can be implanted at the window 51a where the spacers 52 were removed. The source region 13 is made deeper than the etch-back of surface 10a shown in FIGS. 7 and 10, and so this etch-back does not affect the channel length. The insulating capping layer 18 may be formed by oxidation or by TEOS deposition at the window 51a, and may be etched back to allow a good contact to the source region 13.

The p-type channel-accommodating region 15 and p+contact region 35 may be implanted and/or diffused, for example after removing the nitride 51. The depth of the channel-accommodating region 15 can be chosen advantageously in relation to the trench taper, for example in relation to the depths C and D in the particular example of FIG. 10. In each case, the rate of width-reduction (taper) of the trench 20 is greater in the drain drift region 14 than in the channel-accommodating region 15. By introducing the dopant for the region 15 into the upper portion of the semiconductor body part after providing the insulated gate 11 in step (d), the dopant diffusion rate into the lower portion is slowed along the increasingly-tapered side-wall portions of the trench 20 in this lower portion. Thus, this increasing taper can assist in controlling the depth Pz of the p-n junction between regions 14 and 15 adjacent to the sidewall of the trench 20.

The relative depths of the trench 20 and channel-accommodating region 15 can be chosen such that there is very little (in fact hardly any) taper of the trench 20 over at least most of the thickness (depth) of the region 15. Thus, for example, the region 15 may have a depth Pz=C of 1 μm. In this case, the length of the conductive channel 12 in region 15 is unaffected by the trench taper which is used to good advantage in the drain drift region 14, particularly in reducing Qgd.

With a depth Pz=D of 1.2 μm for region 15, the length of the conductive channel 12 is correspondingly increased, and there is also a very small additional increase in its length due to the increasing trench taper over the bottom 0.2 μm of region 15.

With a depth Pz=D of 1.4 μm for region 15, much of the trench taper is within the region 15, but the width of the trench 20 within the drain drift region 14 is very small, i.e. only about 1 μm and less.

For given depths Pz of region 15, this novel trench-gate technology is also versatile enough to allow the cell pitch Yc to be varied so that MOSFET performance can be optimised to meet the different requirements for a control-FET and a synch-FET in VRM applications. Various simulation results are shown in FIGS. 11 to 15. In each case the depth d of the trench 20 was 1.5 μm.

FIG. 11 illustrates the breakdown voltage BVdss in Volts (at an applied gate voltage Vgs=2.5V) as a function of channel length 12z in μm, for different Nepi doping concentrations n in cm⁻³ (3×10¹⁶; 2.5×10¹⁶; 3.5×10¹⁶). In this case, the thickness Nz of the N epi layer 14′ was 5 μm.

FIG. 12 illustrates the specific on-state resistance spRdson in mOhms.mm² (at Vgs=7V) as a function of Nepi doping concentration n in 10¹⁶ donor atoms cm⁻³, for different Nepi thicknesses Nz (5 μm; 4 μm; 3 μm). In this case, the depth Pz of the region 15 was 0.15 μm less than the depth d of the trench 20, i.e. Pz=1.35 μm

FIG. 13 illustrates the on-state drain resistance Rdson in mOhms for a 7.32 mm² active area, as a function of cell pitch Yc in μm, whereas FIG. 14 illustrates the gate-drain charge Qgd in nC at Vds=12V against cell pitch Yc in μm. The different lines plotted in each of FIGS. 13 and 14 are for different depths Pz of the p-type region 15 (1.4 μm; 1.2 μm; 1.0 μm). Measured values (M) are also added to the simulated plot of FIG. 14, for different cell pitches Yc of 4 μm, 2 μm, and 1 μm. These actual measurements fit well with the simulation.

Finally, FIG. 15 illustrates the variation in the Figure of Merit Rdson*Qgd in mOhm s*nC against cell pitch Yc in μm, for the different depths Pz of the p-type region 15 (1.4 μm; 1.2 μm; 1.0 μm).

Thus, this self-aligned technology with novel tapered trench 20 in accordance with the present invention offers enhanced performance, which can meet the very low on-state resistance demand for the synch-Fet through the fabrication of a 1 μm cell pitch and the low switching loss demand for the control-FET through the fabrication of a tapering 0.2 μm trench-gate width.

It will be evident that many modifications and variations are possible within the scope of the present invention.

The conductive gate 11 may be formed of doped polycrystalline silicon as described above. However, other known gate technologies may be used in particular devices, possibly in conjunction the novel features of this invention. Thus, other materials may be used for the whole gate 11 or a part of the gate 11. A material such as a metal silicide or a refractory metal may be used to reduce gate resistance. This material may be used for, for example, the upper part of the gate 11 where the trench 20 is widest.

In the embodiments of FIGS. 1 to 9, the gate dielectric layer 17 lines the bottom as well as the sidewalls of the tapered trench 20. However, other embodiments are possible in which a thicker insulating material 17b is provided at the bottom of the tapered trench 20, as indicated in for example FIG. 10. This thick insulator 17b provides an additional means for reducing the gate-drain capacitance of the device. In this case, before depositing the gate material 11′, TEOS or other insulating material may be deposited to fill the trench 20 and is then etched back until it is left in only the lower part of the trench 20 to form the thick insulator 17b. The tapered shape and rounded bottom of the trench 20 facilitates the deposition of this thick insulating material. It is etched back to a level that is deeper than the region 15 and that may be between, for example, lines D and E of FIG. 10. Thereafter, the thin gate-dielectric layer 17 is provided at the exposed sidewalls of the trench 20 and also at the exposed area of surface 10a, and then the gate material 11′ is deposited. The processing may then be continued as described above.

Although thermal oxides are preferred for a high-quality gate-dielectric layer, the layer 17 could be contour-deposited.

Considerable flexibility is possible in the specific technologies that can be used for forming the various masks, spacers and regions. Thus, further novel features (as well as many features in the prior art) may be used in conjunction with the present invention. In the embodiments described, the mask 51 and spacers 52 are composed of single materials (silicon nitride and silicon oxide). Other embodiments are possible in which composite layers of different materials are used. In this case, for example, a thick composite mask 51 may be used at an early stage in the process, after which the mask 51 may be thinned by removal of an upper part. Even in the case when the original mask 51 of FIG. 3 is wholly of silicon nitride, oxy-nitride is formed at its surface when exposed to oxidising environments as the manufacturing process sequence progresses.

Instead of forming the drain-drift region 14 by an epitaxial layer on a higher-doped substrate 14a, the higher doped region 14a of some devices may be formed by dopant diffusion into the back surface 10b of a high-resistivity substrate that provides the drift region 14. The devices so far described are MOSFETs in which the higher-doped substrate region 14a is of the same conductivity type (n-type in this example) as the drain drift region 14. However, the higher-doped substrate region 14a may be of opposite conductivity type (p-type in this example) to provide an IGBT. The electrode 34 is called an anode electrode in the case of an IGBT.

A vertical discrete device has been illustrated in FIG. 1, having its second main electrode 34 contacting the substrate or other region 14a at the back surface 10b of the body 10. However, an integrated device is also possible in accordance with the invention. In this case, the region 14a may be a doped buried layer between a device substrate and the epitaxial low-doped drain region 14. This buried layer region 14a may be contacted by an electrode 34 at the front major surface 10a, via a doped peripheral contact region which extends from the surface 10a to the depth of the buried layer.

The particular examples described above are n-channel devices, in which the regions 13 and 14 are of n-type conductivity, the regions 15 and 35 are of p-type, and an electron inversion channel 12 is induced in the region 15 by the gate 11. By using opposite conductivity type dopants, a p-channel device can be manufactured by a method in accordance with the invention. In this case, the regions 13 and 14 are of p-type conductivity, the regions 15 and 35 are of n-type, and a hole inversion channel 12 is induced in the region 15 by the gate 11.

Semiconductor materials other than silicon may be used for devices in accordance with the invention, for example silicon carbide.

From reading the present disclosure, other variations and modifications will be apparent to persons skilled in the art. Such variations and modifications may involve equivalent and other features which are already known in the art and which may be used instead of or in addition to features already described herein.

Although specific claims have been formulated in this Application to particular combinations of features, it should be understood that the scope of the disclosure of the present invention also includes any novel feature or any novel combination of features disclosed herein either explicitly or implicitly or any generalisation thereof, whether or not it relates to the main inventive concepts disclosed herein and whether or not it mitigates any or all of the same technical problems as does the presently claimed invention. The Applicants hereby give notice that new claims may be formulated to any such features and/or combinations of such features during the prosecution of the present Application or of any further Applications derived therefrom.

1. A trench-gate field-effect semiconductor device comprising a semiconductor body into which the trench-gate extends from a surface-adjacent source region of a first conductivity type through a channel-accommodating region of a second conductivity type and into an underlying drain drift region of the first conductivity type, wherein the gate trench has a width that is smaller than its depth in the semiconductor body and that tapers increasingly towards the bottom of the gate trench to reduce the width of the trench-gate at a greater rate in the drain drift region than in the channel-accommodating region.

2. A device according to claim 1, wherein the width of the gate trench tapers in the drain drift region to less than 0.7 of its initial width in the channel-accommodating region.

3. A device according to claim 1 or claim 2, wherein the trench-gate is capacitively coupled to the channel-accommodating region across a gate dielectric layer, and the gate dielectric layer lines the side-walls of the gate trench in the drain drift region as well as in the channel-accommodating region.

4. A device according to claim 3, wherein the gate dielectric layer is of substantially uniform thickness along the side-walls of the trench, and the width reduction of the gate trench in the drain drift region reduces gate-drain capacitance as compared with a gate trench of uniform width.

5. A device according to any one of the preceding claims, wherein the rate of width reduction of the trench-gate over a lower one-third (for example a lower 0.5 μm) of the depth of the trench-gate is almost three times that over an upper two-thirds (for example an upper 1 μm) of the depth of the trench-gate.

6. A device according to claim 5, wherein the trench-gate has a depth (for example of 1.5 μm) that is more than six times larger than its width in the channel-accommodating region.

7. A device according to claim 5 or claim 6, wherein there is substantially no taper of the trench-gate over at least most of the depth of the channel-accommodating region.

8. A method of manufacturing a trench-gate field-effect semiconductor device, in which the trench-gate extends from a surface-adjacent source region of a first conductivity type through a channel-accommodating region of a second conductivity type and into an underlying drain drift region of the first conductivity type, and wherein the method includes the following sequence of steps:
(a) providing a semiconductor body having an upper first portion where the channel-accommodating region is present or is to be provided and having a lower second portion that is to provide the drain drift region,
(b) forming on the semiconductor body a mask having a window defining the location and width of a trench to be etched into the semiconductor body for accommodating the trench-gate,
(c) etching the trench to a depth that is greater than its width and that extends so deeply into the semiconductor body that the width of the trench reduces in size towards the bottom of the trench, with the rate of the width reduction of the trench being greater in the lower second portion of the semiconductor body than in the upper first portion of the semiconductor body, and
(d) providing the trench-gate in the trench.

9. A method according to claim 8, wherein the channel-accommodating region is provided in the semiconductor body by introducing dopant of the said opposite conductivity type into the upper first portion of the semiconductor body after the step (d) when the dopant diffusion rate in the lower second portion is slowed along the increasingly-tapered side-wall portions of the trench in the lower second portion.

10. A method according to claim 8 or claim 9, wherein between steps (c) and (d) the trench is lined at least at its side-walls with a silicon dioxide layer that provides at least part of a gate dielectric layer for capacitively coupling the trench-gate to the channel-accommodating region.

11. A method according to any one of claims 8 to 10, wherein the step (b) includes forming the trench-etch window as a narrowed window by providing side-wall extensions at the side-walls of a wider window first formed in the mask.

12. A method according to any one of claims 8 to 11, wherein the additional features of device claims 2 to 7 are also provided.

13. A device according to any one of claims 1 to 7, wherein additional device features resulting from the use of method claims 8 to 12 are also included.
